(19) United States
(12) Patent Application Publication
(10) Pub. No.: US 2007/0146834 A1
(43) Pub. Date: Jun. 28, 2007

(54) Method and apparatus for transmitting fax data

(75) Inventor: Hyung-ho Lee, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/582,975

(22) Filed: Oct. 19, 2006

(30) Foreign Application Priority Data
Dec. 26, 2005 (KR) 2005-129502

(51) Int. Cl. G03F 3/08

(52) U.S. Cl. 358/539; 358/518

(57) ABSTRACT

An apparatus and a method for transmitting fax data. The method includes: compressing a copy to be transmitted using a plurality of compression methods and separately storing each type of compressed data; and transmitting the stored compressed data corresponding to the reception capability of a recipient's facsimile to the recipient's facsimile through communication with the recipient's facsimile.

### CROSS-REFERENCE TO RELATED APPLICATION

This application claims the benefit of Korean Application No. 2005-129502, filed Dec. 26, 2005, in the Korean Intellectual Property Office, the disclosure of which is incorporated herein by reference.

### BACKGROUND OF THE INVENTION

1. Field of the Invention

Aspects of the present invention relate to a transmission of fax data, and, more particularly, to a fax data transmission method and apparatus of transmitting color and monochrome fax data in a facsimile in which a bulk memory (e.g., a hard disk) is installed.

2. Description of the Related Art

Conventional fax data transmission methods are classified into methods of directly transmitting fax data and methods of storing fax data in a memory and transmitting the stored fax data. Since conventional methods of storing fax data in a memory and transmitting the stored fax data tend to support only monochrome data, the monochrome data is compressed using a T4/T6 compression method based on International Telecommunications Union Telecommunication Standardization Sector (ITU-T) Recommendations T.4/T.6, before transmission. In most cases, the monochrome data is stored in the memory in a Modified Modified Read (MMR) data format, and when scanning and compression of all loaded copies are completed, communication is started by the dialing of an inputted fax number. If the communication is connected, the monochrome data stored in the memory is transmitted to the recipient in a T4/T6 compressed data format (Modified Huffman (MH), Modified Read (MR), or MMR) by referring to digital identification signal (DIS) information of the recipient. If a plurality of fax numbers is inputted, the monochrome data stored in the memory is transmitted to every recipient by repeating the same process as described above for all the input fax numbers.

Since the conventional method of storing fax data in a memory and transmitting the stored fax data supports only monochrome data, a color image may be transmitted only using the method of directly transmitting fax data. In this case, when the same image is transmitted to several recipients, the direct transmission must be repeated several times.

In addition, when a memory transmission function is used to transmit monochrome data, the monochrome data is stored in the memory using the T4/T6 compression method, which is inefficient and slow to transmit compared to a Joint Bi-level Image Experts Group (JBIG) compression method.

### SUMMARY OF THE INVENTION

Aspects of the present invention provide a fax data transmission method and apparatus to perform a memory transmission function regardless of the reception capability of a recipient's facsimile.

According to an aspect of the present invention, there is provided a method of transmitting fax data in a memory transmission mode of a sender's facsimile, the method comprising: compressing a copy to be transmitted using a plurality of compression methods and separately storing each of the compressed data of each compression method; and transmitting the stored compressed data corresponding to the reception capability of a recipient's facsimile to the recipient's facsimile through communication with the recipient's facsimile.

According to another aspect of the present invention, there is provided an apparatus for transmitting fax data in a memory transmission mode of a sender's facsimile, the apparatus comprising: a compressed data generator to compress a copy to be transmitted using a plurality of compression methods; a data storage unit to separately store the compressed data generated using each of the compression methods; and a data transmission controller to transmit the stored compressed data corresponding to the reception capability of a recipient's facsimile to the recipient's facsimile through communication with the recipient's facsimile.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become more apparent and more readily appreciated from the following description of the embodiments, taken in conjunction with the accompanying drawings of which:

FIG. 1 is a flowchart of a fax data transmission method according to an embodiment of the present invention;

FIG. 2 is a flowchart showing operation 10 of FIG. 1 in detail;

FIG. 3 shows data obtained by compressing fax data according to an embodiment of the present invention;

FIG. 4 is a flowchart showing operation 12 of FIG. 1 in detail; and

FIG. 5 is a block diagram of a fax data transmission apparatus according to an embodiment of the present invention.

### DETAILED DESCRIPTION OF THE EMBODIMENTS

Reference will now be made in detail to present embodiments of the present invention, examples of which are illustrated in the accompanying drawings, wherein like reference numerals refer to the like elements throughout. The embodiments are described below in order to explain the present invention by referring to the figures.

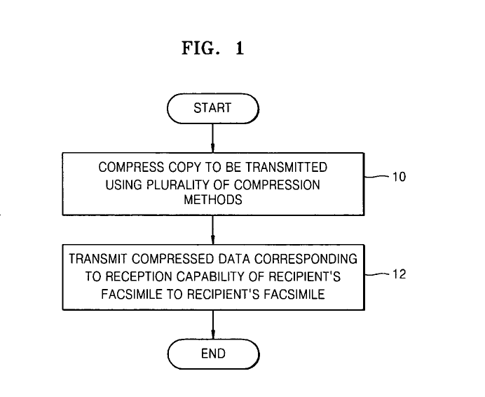

FIG. 1 is a flowchart of a fax data transmission method according to an embodiment of the present invention. As shown in FIG. 1, when the sender's facsimile is set to a memory transmission mode, a copy to be transmitted is compressed using a plurality of compression methods, and the compressed data is stored separately in operation 10.

The plurality of compression methods includes Joint Photographic Experts Group (JPEG), JBIG, and T4/T6 compression methods. JPEG is an international standard developed for compression of a digitized color image with the support of the International Organization of Standardization (ISO) and the International Telegraph and Telephone Consultative Committee (CCITT). JPEG compression is a compression format to compress an image into a series of dots or pixels.

JBIG is a new technology developed with the support of ISO and the CCITT to compress monochrome data, and was recommended as an international standard in 1993. JBIG has a high compression ratio of at least three times that of Group 4 fax.

T4/T6 compression is a standard for compressing binary data, and is classified into ITU-T T.4 (MR/MH) for common G3 facsimiles connected to a telephone line and ITU-T T.6 (MMR) for high speed G4 facsimiles connected to an ISDN network.

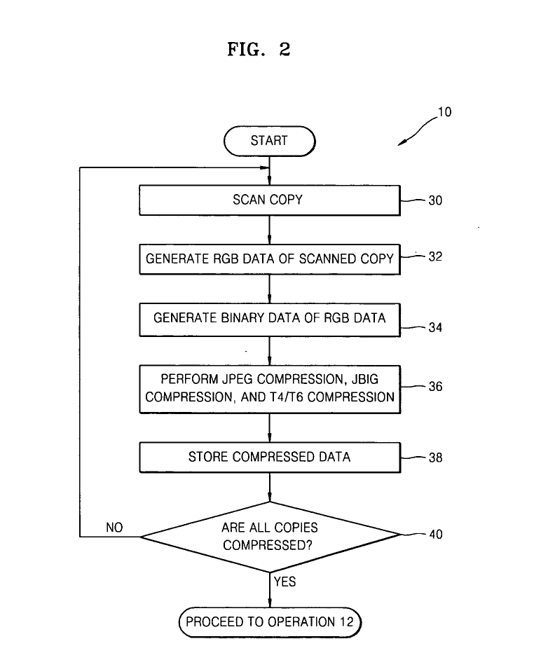

FIG. 2 is a flowchart showing operation 10 of FIG. 1 in As shown in FIG. 2, in operation 30, a copy is scanned. In operation 32, RGB data of the scanned copy is generated. In operation 34, binary data of the RGB data is generated. In operation 36, JPEG compression of the RGB data, and JBIG compression and T4/T6 compression of the binary data are respectively performed. In operation 38, the compressed data is stored. That is, the generated JPEG compressed data, JBIG compressed data, and T4/T6 compressed data are stored in a bulk memory. In operation 40, whether all copies have been compressed is determined. If all the copies have not been compressed, the remaining copies are compressed to the three data formats by repeating operations 30 through 38. If all the copies have been compressed, the process proceeds to operation 12 of FIG. 1.

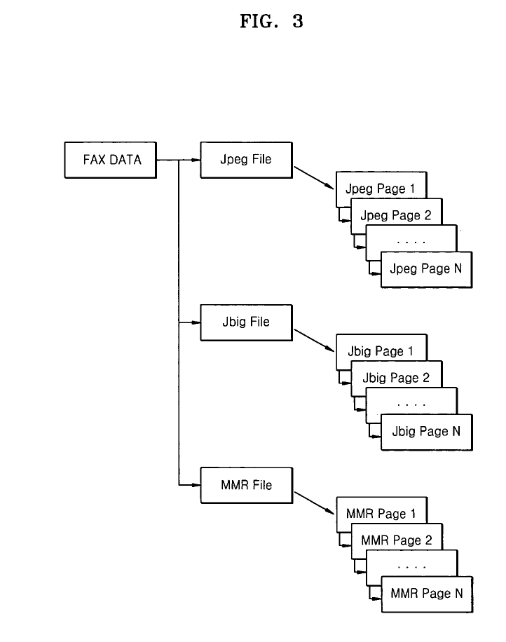

FIG. 3 shows data that is obtained by the compression of fax data according to an embodiment of the present invention. As illustrated in FIG. 3, the fax data to be transmitted to a recipient's facsimile is compressed into JPEG compressed data, JBIG compressed data, and T4/T6 compressed data, and separately stored.

Referring back to FIG. 1, in operation 12, compressed data corresponding to the reception capability of the recipient's facsimile is transmitted to the recipient's facsimile by communicating with the recipient's facsimile. The reception capability of the recipient's facsimile refers to the capability of the recipient to receive JPEG compressed data, JBIG compressed data, and T4/T6 compressed data.

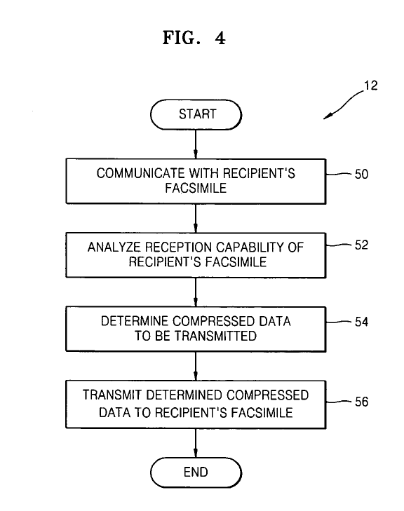

FIG. 4 is a flowchart showing operation 12 of FIG. 1 in detail. As shown in FIG. 4, in operation 50, the sender's facsimile communicates with the recipient's facsimile. In operation 52, compressed data to be transmitted is determined according to a result of an analysis of the reception capability of the recipient. If the recipient's facsimile is able to receive data of a plurality of compression methods, the compressed data to be transmitted is determined in a predetermined transmission order. The predetermined transmission order may be first JPEG, second JBIG, and last T4/T6.

According to an embodiment of the invention, the predetermined transmission order may be set by default or selectable by the sender using an input panel. For example, if the recipient's facsimile is able to receive JPEG compressed data and T4/T6 compressed data, JPEG compressed data may be transmitted. If the recipient's facsimile is able to receive JPEG compressed data, the JPEG compressed data is transmitted so that the recipient's facsimile receives color data. If the recipient's facsimile is able to receive JBIG compressed data and T4/T6 compressed data, JBIG compressed data may be transmitted. If the recipient's facsimile is able to receive JBIG compressed data, JBIG compressed data is transmitted so that the recipient's facsimile receives monochrome data. If the recipient's facsimile is able to receive JPEG compressed data, JBIG compressed data, and T4/T6 compressed data, JPEG compressed data may be transmitted. If the recipient's facsimile is able to receive JPEG compressed data, JPEG compressed data is transmitted so that the recipient's facsimile receives color data. If the recipient's facsimile is able to receive only T4/T6 compressed data, T4/T6 compressed data may be transmitted.

In operation 56, the selected compressed data is transmitted to the recipient's facsimile.

The embodiments of the present invention may be written as code/instructions/computer programs and may be implemented in general-use digital computers that execute the code/instructions/computer programs using a computer readable recording medium. Examples of the computer readable recording medium include magnetic storage media (e.g. ROM, floppy disks, hard disks, etc.), optical recording media (e.g. CD-ROMs, or DVDs), and storage media, such as carrier waves (e.g. transmission through the Internet), or combinations thereof. The computer readable recording medium may also be distributed over network coupled computer systems so that the computer readable code is stored and executed in a distributed fashion. Also, functional programs, code, and code segments to accomplish the present invention may be relatively easily construed by programmers skilled in the art to which the present invention pertains.

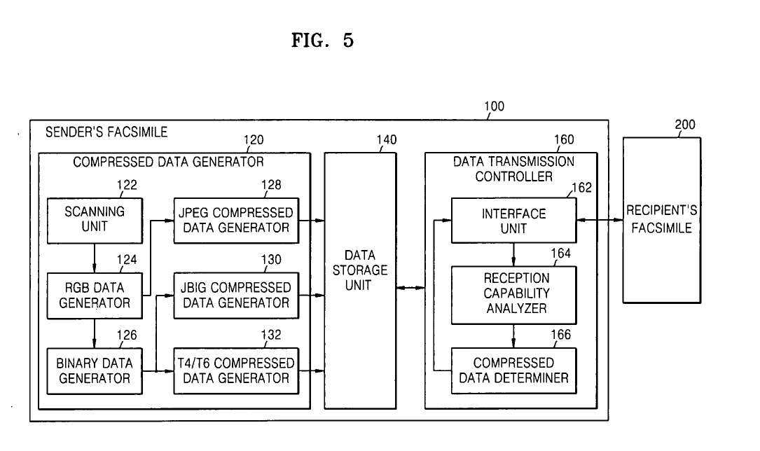

A fax data transmission apparatus according to an embodiment of the present invention will now be described in detail with reference to FIG. 5. FIG. 5 is a block diagram of a fax data transmission apparatus according to an embodiment of the present invention. The fax data transmission apparatus includes a sender's facsimile 100 and a recipient's facsimile 200. The sender's facsimile 100 includes a compressed data generator 120, a data storage unit 140, and a data transmission controller 160.

In a memory transmission mode of the sender's facsimile 100, the compressed data generator 120 compresses a copy to be transmitted using a plurality of compression methods and outputs the compressed data to the data storage unit 140. In particular, the sender's facsimile 100 uses the JPEG, JBIG, and T4/T6 compression methods as the plurality of compression methods.

The compressed data generator 120 includes a scanning unit 122, an RGB data generator 124, a binary data generator 126, a JPEG compressed data generator 128, a JBIG compressed data generator 130, and a T4/T6 compressed data generator 132. The scanning unit 122 scans a copy and outputs the scanning result to the RGB data generator 124. The RGB data generator 124 generates RGB data of the copy scanned by the scanning unit 122 and outputs the RGB data to the binary data generator 126 and the JPEG compressed data generator 128. The binary data generator 126 generates binary data of the RGB data generated by the RGB data generator 124 and outputs the binary data to the JBIG compressed data generator 130 and the T4/T6 compressed data generator 132. The JPEG compressed data generator 128 performs JPEG compression of the RGB data generated by the RGB data generator 124 and outputs the JPEG compressed data to the data storage unit 140. The JBIG compressed data generator 130 performs JBIG compression of the binary data generated by the binary data generator 126 and outputs the JBIG compressed data to the data storage unit 140. The T4/T6 compressed data generator 132 performs T4/T6 compression of the binary data generated by the binary data generator 126 and outputs the T4/T6 compressed data to the data storage unit 140.

The data storage unit 140 separately stores the compressed data generated using the different compression methods. The data storage unit 140 separately stores the JPEG compressed data input from the JPEG compressed data generator 128, the JBIG compressed data input from the JBIG compressed data generator 130, and the T4/T6 compressed data input from the T4/T6 compressed data generator 132, and outputs one of them to the data transmission controller 160 according to an output request of the data transmission controller 160.

The data transmission controller 160 reads compressed data corresponding to the reception capability of the recipient's facsimile 200 from the data storage unit 140 by communicating with the recipient's facsimile 200 and transmits the read compressed data to the recipient's facsimile 200. The data transmission controller 160 includes an interface unit 162, a reception capability analyzer 164, and a compressed data determiner 166. The interface unit 162 communicates with the recipient's facsimile 200. The interface unit 162 performs an interfacing operation in which compressed data is transmitted to the recipient's facsimile 200 and information on the reception capability of the recipient's facsimile 200 is received.

The reception capability analyzer 164 analyzes the reception capability of the recipient's facsimile 200 and outputs a result of the analysis to the compressed data determiner 166. In particular, the reception capability analyzer 164 analyzes the reception capability of the recipient's facsimile 200 using DIS protocol information of the recipient's facsimile 200 received through the interface unit 162.

The compressed data determiner 166 determines which type of compressed data to transmit according to the result of the reception capability analysis and outputs the determination result to the interface unit 162. In particular, if the recipient's facsimile 200 is determined to be able to receive data of a plurality of compression methods, the compressed data determiner 166 determines that the compressed data is to be transmitted in a predetermined transmission order. The predetermined transmission order may be first JPEG, second JBIG, and last T4/T6. The predetermined transmission order may be set by default or selectable by the sender using an input panel. For example, if the recipient's facsimile 200 is able to receive JPEG compressed data and T4/T6 compressed data, the compressed data determiner 166 determines that JPEG compressed data is to be transmitted.

If it is determined that the recipient's facsimile 200 is able to receive JBIG compressed data and T4/T6 compressed data, the compressed data determiner 166 determines that JBIG compressed data is to be transmitted. If it is determined that the recipient's facsimile 200 is able to receive JPEG compressed data, JBIG compressed data, and T4/T6 compressed data, the compressed data determiner 166 determines that JPEG compressed data is to be transmitted. If it is determined that the recipient's facsimile 200 is able to receive only T4/T6 compressed data, the compressed data determiner 166 determines that T4/T6 compressed data is to be transmitted.

The interface unit 162 transmits the selected compressed data to the recipient's facsimile 200.

As is described above, in a fax data transmission method and apparatus according to embodiments of the present invention, the transmission of color data is supported in a memory transmission mode of fax data, and, when the color data is transmitted, the sender may transmit the same image to several recipients at once. In addition, in a monochrome data memory transmission mode, by transmitting data using JBIG compression, which has a higher compression ratio than T4/T6 compression, data transmission time may be reduced. Further, a memory transmission function may be used regardless of the reception capability of a recipient's facsimile. Still further, color fax data and monochrome fax data may be transmitted by generating data in three compression formats for each copy, storing the generated data in a bulk memory, and transmitting JPEG compressed data, JBIG compressed data, or T4/T6 compressed data according to DIS protocol information of the recipient's facsimile.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A method of transmitting fax data in a memory transmission mode of a facsimile of a sender, the method comprising:
compressing a copy to be transmitted using a plurality of compression methods and separately storing the compressed data of each compression method; and
transmitting the stored compressed data corresponding to a reception capability of a facsimile of a recipient to the facsimile of the recipient through communication with the facsimile of the recipient.

2. The method of claim 1, wherein the plurality of compression methods comprise Joint Photographic Experts Group (JPEG), Joint Bi-level Image Experts Group (JBIG), and T4/T6 compression methods.

3. The method of claim 1, wherein the compressing comprises:
scanning the copy;
generating RGB data of the scanned copy;
generating binary data of the RGB data;
performing JPEG compression of the RGB data, and performing JBIG compression and T4/T6 compression of the binary data, to generate compressed data; and
storing the compressed data.

4. The method of claim 3, wherein the compressing further comprises determining whether all copies have been compressed.

5. The method of claim 1, wherein the transmitting comprises:
communicating with the facsimile of the recipient;
analyzing the reception capability of the facsimile of the recipient;
determining which compressed data is to be transmitted according to a result of the reception capability analysis; and
transmitting the determined compressed data to the facsimile of the recipient.

6. The method of claim 5, wherein, during the analyzing, the reception capability of the facsimile of the recipient is analyzed using digital identification signal (DIS) protocol information of the facsimile of the recipient.

7. The method of claim 5, wherein, during the determining, if the facsimile of the recipient receives compressed data generated using the plurality of compression methods, the compressed data to be transmitted is determined according to a predetermined transmission order.

8. The method of claim 7, wherein the predetermined transmission order is JPEG first, JBIG second, and T4/T6 last.

9. The method of claim 7, wherein the predetermined transmission order is set by default and/or is selectable by the sender.

10. A computer readable recording medium storing a computer readable program to execute the method of claim 1.

11. An apparatus to transmit fax data in a memory transmission mode of a facsimile of a sender, the apparatus comprising:
a compressed data generator to compress a copy to be transmitted using a plurality of compression methods;
a data storage unit to separately store the compressed data generated using each of the compression methods; and
a data transmission controller to transmit the stored compressed data corresponding to a reception capability of a facsimile of a recipient to the facsimile of the recipient through communication with the facsimile of the recipient.

12. The apparatus of claim 11, wherein the plurality of compression methods comprise Joint Photographic Experts Group (JPEG), Joint Bi-level Image Experts Group (JBIG), and T4/T6 compression methods.

13. The apparatus of claim 11, wherein the compressed data generator comprises:
a scanning unit to scan the copy;
an RGB data generator to generate RGB data of the scanned copy;
a binary data generator to generate binary data of the RGB data;
a JPEG compressed data generator to perform JPEG compression of the RGB data;
a JBIG compressed data generator to perform JBIG compression of the binary data; and
a T4/T6 compressed data generator to perform T4/T6 compression of the binary data.

14. The apparatus of claim 11, wherein the data transmission controller comprises:
an interface unit to communicate with the facsimile of the recipient;
a reception capability analyzer to analyze a reception capability of the facsimile of the recipient; and
a compressed data determiner to determine which compressed data is to be transmitted according to a result of the reception capability analysis, wherein the interface unit transmits the determined compressed data to the facsimile of the recipient.

15. The apparatus of claim 14, wherein the reception capability analyzer analyzes the reception capability of the facsimile of the recipient using digital identification signal (DIS) protocol information of the facsimile of the recipient.

16. The apparatus of claim 14, wherein the compressed data determiner determines the compressed data to be transmitted according to a predetermined transmission order if the facsimile of the recipient receives compressed data generated using the plurality of compression methods.

17. The apparatus of claim 16, wherein the predetermined transmission order is JPEG first, JBIG second, and T4/T6 last.

18. The apparatus of claim 16, wherein the predetermined transmission order is set by default or is selectable by the sender.

19. A method of transmitting image data in a memory transmission mode of a first device, the method comprising:
compressing the image data using a plurality of compression methods to generate sets of compressed data for each compression method;
storing the compressed data of each compression method; and
transmitting to a second device the stored compressed data corresponding to a reception capability of the second device.

20. The method of claim 19, wherein the compression methods comprise Joint Photographic Experts Group (JPEG), Joint Bi-level Image Experts Group (JBIG), and T4/T6 compression methods.

21. The method of claim 19, wherein the compressing comprises:
generating RGB data of the image data;
generating binary data of the RGB data; and
performing JPEG compression of the RGB data, and performing JBIG compression and T4/T6 compression of the binary data, to generate the sets of compressed data for each compression method.

22. The method of claim 19, wherein the transmitting comprises:
communicating with the second device;
analyzing the reception capability of the second device;
determining which compressed data is to be transmitted according to a result of the reception capability analysis; and
transmitting the determined compressed data to the second device.

23. The method of claim 22, wherein, during the analyzing, the reception capability of the second device is analyzed using digital identification signal (DIS) protocol information of the second device.

24. The method of claim 22, wherein, during the determining, if the second device receives compressed data generated using the plurality of compression methods, the compressed data to be transmitted is determined according to a predetermined transmission order that is set by default or by a selection of a user.

25. A computer readable recording medium storing a computer readable program to execute the method of claim 19.

26. An apparatus to transmit image data in a memory transmission mode of a first device, the apparatus comprising:
a compressed data generator to compress the image data using a plurality of compression methods to generate sets of compressed data for each compression method;
a data storage unit to separately store the compressed data of each compression method; and
a data transmission controller to transmit the stored compressed data corresponding to a reception capability of a second device to the second device.

27. The apparatus of claim 26, wherein the plurality of compression methods comprise Joint Photographic Experts Group (JPEG), Joint Bi-level Image Experts Group (JBIG), and T4/T6 compression methods.

28. The apparatus of claim 26, wherein the compressed data generator comprises:
a scanning unit to scan an image corresponding to the image data;
an RGB data generator to generate RGB data of the image data;
a binary data generator to generate binary data of the RGB data;
a JPEG compressed data generator to perform JPEG compression of the RGB data;
a JBIG compressed data generator to perform JBIG compression of the binary data; and
a T4/T6 compressed data generator to perform T4/T6 compression of the binary data.

29. The apparatus of claim 26, wherein the data transmission controller comprises:
an interface unit to communicate with the second device;
a reception capability analyzer to analyze a reception capability of the second device; and
a compressed data determiner to determine which compressed data is to be transmitted according to a result of the reception capability analysis, wherein the interface unit transmits the determined compressed data to the second device.

30. The apparatus of claim 29, wherein the reception capability analyzer analyzes the reception capability of the second device using digital identification signal (DIS) protocol information of the second device.

31. The apparatus of claim 29, wherein the compressed data determiner determines the compressed data to be transmitted according to a predetermined transmission order if the second device receives compressed data generated using the plurality of compression methods, the predetermined order being set by default or by a selection of a user.

32. A method of transmitting image data from a first device, the method comprising:
compressing the image data using a plurality of compression methods to generate sets of compressed data for each compression method to be stored; and
transmitting the stored compressed data corresponding to a reception capability of a second device to the second device.
